(19) United States
(12) Patent Application Publication
(10) Pub. No.: US 2012/0275115 A1
(43) Pub. Date: Nov. 1, 2012

(54) ELECTRONIC DEVICE

(75) Inventor: Ching-Hua Chen, Taipei City (TW)

(73) Assignee: ASUSTEK COMPUTER INC., Taipei City (TW)

(21) Appl. No.: 13/457,509

(22) Filed: Apr. 27, 2012

Related U.S. Application Data
(60) Provisional application No. 61/480,357, filed on Apr. 28, 2011.

(51) Int. Cl. H05K 7/20

(52) U.S. Cl. 361/697

(57) ABSTRACT

An electronic device including a casing, a heat generating element, a heat dissipating element and a fan is provided. The heat generating element is disposed in the casing. The heat dissipating element is disposed on the heat generating element. The fan is disposed on the heat dissipating element and is capable of rotating forward or reverse. When the electronic device in a first state is changed into a second state, the fan firstly rotates reverse to generate a first airflow for removing the dust in the casing. After the fan rotates reverse over a period of time, the fan stops from rotating reverse and starts to rotate forward to generate a second airflow for dissipating heat from the heat dissipating element.

### CROSS-REFERENCE TO RELATED APPLICATION

This application claims the priority benefit of U.S. Provisional Application Ser. No. 61/480,357, filed on Apr. 28, 2011. The entirety of the above-mentioned patent application is hereby incorporated by reference herein and made a part of this specification.

### BACKGROUND OF THE INVENTION

1. Field of the Invention

The invention relates to an electronic device. Particularly, the invention relates to an electronic device having a cooler.

2. Description of Related Art

Along with development of technology, various electronic devices increasingly fill people's daily life, for example, desktop computers, servers, business machines, home appliances and communication and instrument equipment, etc., and heat dissipating of the electronic devices is an important issue in application of the electronic devices. Regarding a general computer, a main heating source is a central processing unit (CPU), and a heating amount thereof is increased as an operating speed thereof increases, so that a compulsory heat dissipating method has to be used to reduce an operating temperature of the CPU, so as to maintain a normal operation of the CPU.

A conventional heat dissipating method is mainly based on convection and conduction, for example, a heat dissipating element (for example, a heat sink) is disposed on a heating generating element, and a fan is disposed on the heat dissipating element to generate airflow for dissipating heat. However, since a direction of the airflow generated by the fan is fixed, after long time usage of the electronic device, a lot of dust is generally accumulated on the heat dissipating element, which is inconvenient to clean.

### SUMMARY OF THE INVENTION

The invention is directed to an electronic device, and dust in the electronic device is conveniently cleaned through forward rotation or reverse rotation of a fan.

The invention provides an electronic device including a casing, a heat generating element, a heat dissipating element and a first fan. The heat generating element is disposed in the casing. The heat dissipating element is disposed on the heat generating element. The first fan is disposed on the heat dissipating element, where when the electronic device is changed from a first state into a second state, the first fan rotates reverse to generate a first airflow. After the first fan rotates reverse over a first time length, the first fan is changed to rotate forward to generate a second airflow.

In the invention, the first airflow is generated through reverse rotation of the first fan, and the second airflow is generated through forward rotation of the first fan. The first state represents that the electronic device is in a turn-off state, and the second state represents that the electronic device is in a turn-on state. The first airflow flows from the heat dissipating element to the first fan, and the second airflow flows from the first fan to the heat dissipating element.

In the invention, the electronic device further includes a second fan, which is disposed in the casing and is adapted to generate a third airflow and a fourth airflow, where after the fourth airflow is maintained over a second time length, the second fan generates the third airflow. The first time length is greater than the second time length. The third airflow flows to an internal space of the casing. The fourth airflow flows through a motherboard.

The first fan disposed on the heat dissipating element is not only capable of rotating forward to dissipate the heat of the heat dissipating element, but is also capable of rotating reversely to remove dust in the casing, so as to avoid accumulation of the dust in the casing to reduce heat dissipating efficiency.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a three-dimensional view of an electronic device according to an embodiment of the invention.

FIG. 2 is a top view of the electronic device of FIG. 1.

FIG. 3 is a block diagram of a control module of FIG. 1.

FIG. 4 is a top view of an electronic device according to another embodiment of the invention.

FIG. 5 is a top view of an electronic device according to still another embodiment of the invention.

### DETAILED DESCRIPTION OF DISCLOSED EMBODIMENTS

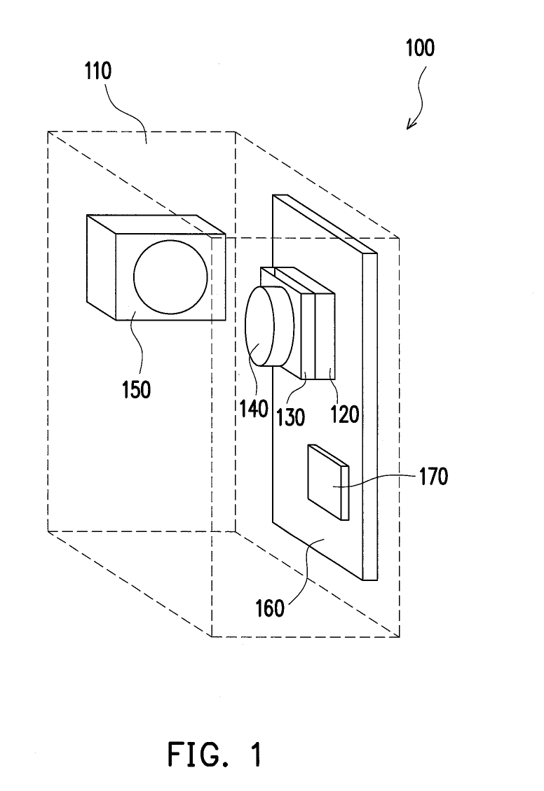

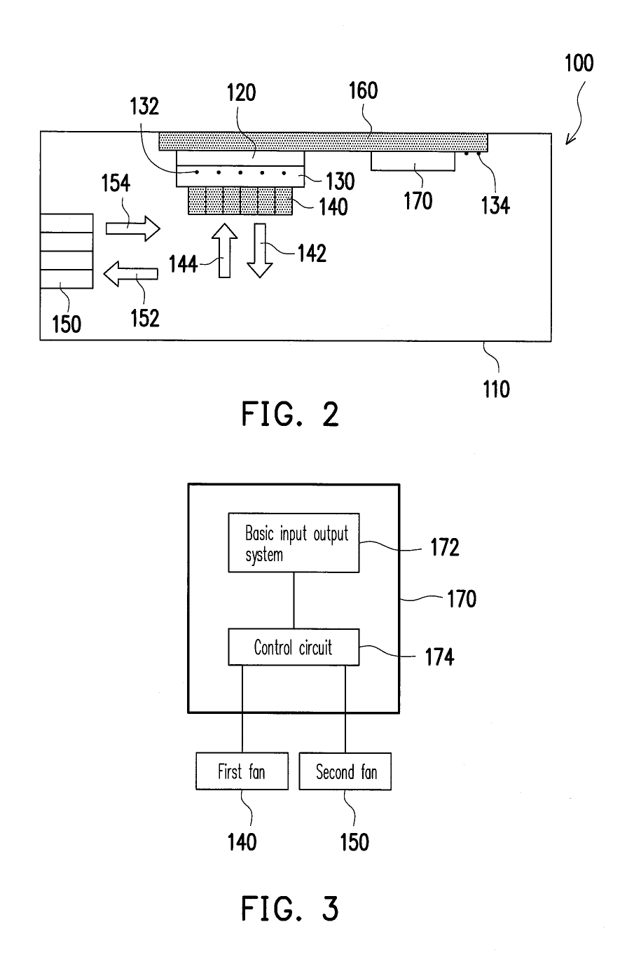

FIG. 1 is a three-dimensional view of an electronic device according to an embodiment of the invention. FIG. 2 is a top view of the electronic device of FIG. 1. Referring to FIG. 1 and FIG. 2, the electronic device 100 includes a casing 110, a heat generating element 120, a heat dissipating element 130 and a first fan 140. The heat generating element 120 is disposed in the casing 110, and the heat dissipating element 130 is disposed on the heat generating element 120. In the present embodiment, the electronic device 100 is, for example, a host of a desktop computer, which includes a motherboard 160, and the motherboard 160 is disposed in the casing 110. The heat generating element 120 is, for example, a central processing unit (CPU) and is disposed on the motherboard 160. The heat dissipating element 130 can be a general heat sink, which is disposed on the heat generating element 120. The first fan 140 is a fan corresponding to the CPU.

The first fan 140 is disposed on the heat dissipating element 130, and in the present embodiment, the first fan 140 can rotate forward or reversely. When the first fan 140 of the electronic device 100 rotates reverse, a first airflow 142 is generated to remove dust on the heat dissipating element 130, and when the first fan 140 rotates forward, a second airflow 144 is generated to dissipating heat on the heat dissipating element 130.

For example, an operating method of the first fan 140 can be set according to a following method. In the present embodiment, the electronic device 100 can operate in two operating states, which are respectively a turn-on state (a first state) or a turn-off state (a second state), and the fan can rotate forward or reversely along with the operating states of the electronic device 100.

When the electronic device 100 is changed from the turn-off state (the first state) to the turn-on state (the second state), the first fan 140 of the electronic device 100 first rotates reverse to generate the first airflow 142, so as to remove the dust 132 adhered to a surface of the heat dissipating element 130, and expel the dust 132 to the outside of the electronic device 100. After the first fan 140 rotates reverse over a first time length, the first fan 140 stops rotating reverse, and starts to rotate forward, so as to generate the second airflow 144 to dissipate the heat of the heat dissipating element 130.

As described above, the first fan 140 of the electronic device 100 is not only capable of rotating forward to dissipate the heat of the heat dissipating element 130, but is also capable of rotating reverse to remove the dust accumulated in the internal of the electronic device 100 and accumulated on the heat dissipating element 130. In this way, removal of the dust of the heat dissipating element 130 can be more convenient, so as to avoid accumulation of the dust on the heat dissipating element 130 to reduce heat dissipating efficiency.

Besides the first fan 140, in the present embodiment, the electronic device 100 further includes a plurality of fan devices capable of rotating forward or reverse. Referring to FIG. 2, the electronic device 100 further includes a second fan 150. The second fan 150 is, for example, a system fan of the host, and the second fan 150 can also rotate forward or reverse to generate a third airflow 152 or a fourth airflow 154, where the different airflows are respectively used to dissipate heat or remove dust in an internal space of the casing 110. In the present embodiment, the third airflow 152 generated through the forward rotation of the second fan 150 is used to expel the dust 132 distributed within the internal space of the casing 110 to the outside of the casing 110.

As shown in FIG. 2, when the electronic device 100 is changed from the first state to the second state, as described above, the first fan 140 first rotates reverse over a specific time length, so as to generate the first airflow 142 used for removing the dust 132. The first airflow 142 generated through the reverse rotation of the first fan 140 is used to blow the dust 132 adhered to the heat dissipating element 130, meanwhile, the second fan 150 also starts to rotate reverse to generate the fourth airflow 154, which is adapted to blow the dust 134 on the motherboard 160 for distributing in the internal space of the casing 110. After a specific time length, both of the first fan 140 and the second fan 150 stop rotating reverse, and respectively start to rotate forward. Now, the second fan 150 rotates forward, and since the second fan 150 is the system fan and is disposed on the casing 110, where vent holes are configured on the casing 110 corresponding to a position of the second fan 150, the third airflow 152 generated by the second fan 150 can expel all of the dusts (including the dust 132 blown by the first fan 140 in the reverse rotation state and the dust 134 blown by the second fan 150 in the reverse rotation state) distributed in the internal space of the casing 110 to the outside of the casing 110.

In the present embodiment, the aforementioned specific time lengths are different on the first fan 140 and the second fan 150, for example, the specific time length for the second fan 150 rotating reverse is set to be greater than the specific time length for the first fan 140 rotating reverse. In other words, after the second specific time length is terminated and the second fan 150 starts to rotate forward, the first fan 140 still rotates reverse until the corresponding specific time length is terminated. During the period that the first fan 140 rotates reverse and the second fan 150 rotates forward, the third airflow 152 generated through the forward rotation of the second fan 150 can expel the dust 132 and the dust 134.

The specific time length is, for example, 30 seconds or 20 seconds, though the invention is not limited thereto, and the specific time length can be set to other suitable values, which is determined by the user.

In the present embodiment, the first fan 140 and the second fan 150 are set to rotate reverse to remove the dusts in the electronic device 100 when the electronic device 100 is changed from the turn-off state to the turn-on state. However, the invention is not limited thereto, and in other embodiments, the first fan 140 (and the second fan 150) can be set to rotate reverse to remove the dusts when the electronic device 100 is activated from a hibernation state, and the time length for dust removal and an operation sequence are the same to that of the aforementioned embodiment, and details thereof are not repeated. Moreover, when the electronic device 100 is in the second state, the first fan 140 (and the second fan 150) can be set to start rotating reverse to remove the dust at a predetermined time, and a time length for the dust removal and the operation sequence are the same to that of the aforementioned embodiment, and details thereof are not repeated. For example, the first fan 140 (and the second fan 150) can be set to start rotating reverse to remove the dust at a specific time (for example, 9 o'clock in the morning) on a specific day (for example, Sunday) every week.

A method for configuring the fans of the electronic device 100 is described below. FIG. 3 is a block diagram of a control module of FIG. 1. Referring to FIG. 3, in order to set the operations of the first fan 140 and the second fan 150, the electronic device 100 further includes a control module 170. The control module 170 is disposed on the motherboard 160 and is used for driving the first fan 140 and the second fan 150 to perform the reverse rotations to remove the dust. In detail, the control module 170 includes a basic input output system (BIOS) 172 and a control circuit 174. The BIOS 172 is electrically connected to the first fan 140 and the second fan 150, and the control circuit 174 is also electrically connected to the first fan 140 and the second fan 150.

The electronic device 100 can set the first fan 140 and the second fan 150 to a low rotation speed, a medium rotation speed or a high rotation speed through the BIOS 172. The low rotation speed corresponds to lower noise, the high rotation speed corresponds to a better dust removal effect, and noise and a dust removal effect corresponding to the medium rotation speed are between that of the low rotation speed and that of the high rotation speed. For example, when the user uses the electronic device 100 in a normal operation mode, the first fan 140 and the second fan 150 can be adjusted to the low rotation speed, so as to reduce the noise of the fans of the electronic device 100. Comparatively, if the user has a demand in performance (for example, over clocking), the first fan 140 and the second fan 150 can be adjusted to the high rotation speed to increase the heat dissipating efficiency. Moreover, reverse rotation speeds of the first fan 140 and the second fan 150 can be set to be higher than forward rotation speeds thereof, so as to achieve a better dust removal effect. In addition, a predetermined time can be set through the BIOS 172, and under the second state, the electronic device 100 drives the first fan 140 and the second fan 150 to rotate reverse to remove the dust at the predetermined time.

Configuration of the control circuit 174 allows the user to actively set the first fan 140 and the second fan 150 to rotate forward or reverse. For example, when the first fan 140 and the second fan 150 of the electronic device 100 rotate forward to dissipate the heat, the user can operate the control circuit 174 through an operation interface of the electronic device 100 to drive the first fan 140 and the second fan 150 to start rotating reverse to remove the dust. Comparatively, when the first fan 140 and the second fan 150 of the electronic device 100 rotate reverse to remove the dust, the user can operate the control circuit 174 through the operation interface of the electronic device 100 to drive the first fan 140 and the second fan 150 to start rotating forward to dissipate the heat.

Moreover, when a temperature in the casing 110 is greater than a predetermined value, the BIOS 172 can confine the first fan 140 and the second fan 150 to only be able to rotate forward, so as to avoid a situation that the first fan 140 and the second fan 150 rotate reverse to reduce the heat dissipating performance of the system that probably causes damage of the components or compulsory shut-down of the electronic device 100.

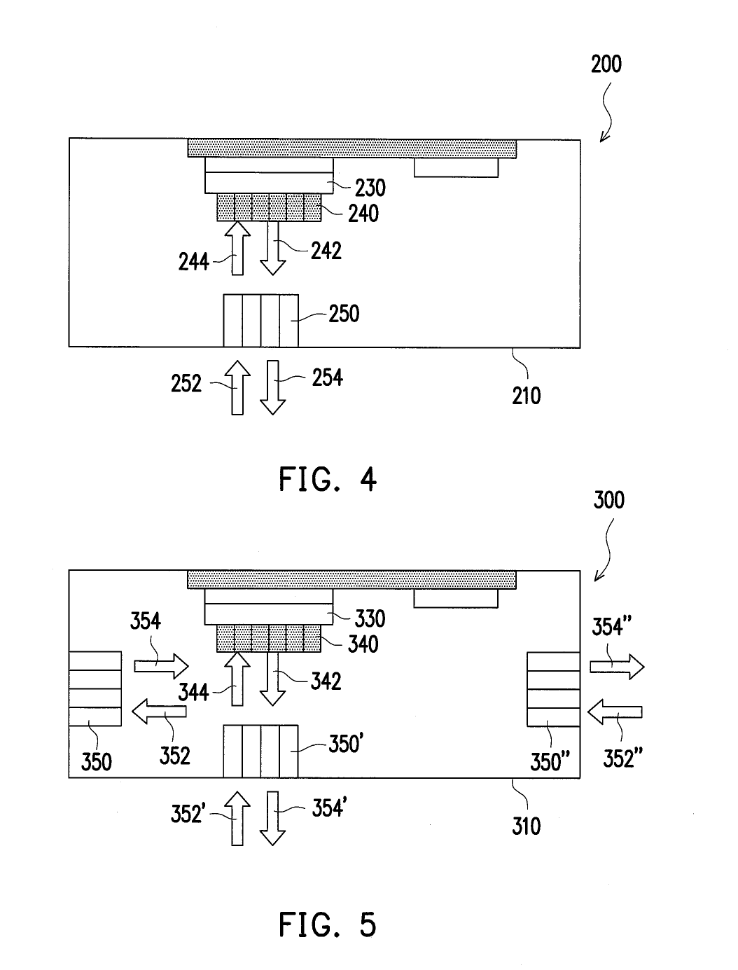

Positions and the number of the second fans 150 are not limited by the invention, which is described below. FIG. 4 is a top view of an electronic device according to another embodiment of the invention. In the electronic device 200 of the present embodiment, configuration and operation of a first fan 240 are the same to that of the first fan 140 of FIG. 2, which are not repeated. A main difference between the electronic device 200 and the electronic device 100 is that a second fan 250 is disposed on a casing 210 at a position corresponding to the first fan 240. When the first fan 240 rotates reverse to generate a first airflow 242 to remove the dust on a heat dissipating element 230, the second fan 250 also rotates reverse to generate a fourth airflow 254, where the fourth airflow 254 and the first airflow 242 have a same direction, so as to improve the dust removal effect. When the first fan 240 rotates forward to generate a second airflow 244 to dissipate the heat of the heat dissipating element 230, the second fan 250 also rotates forward to generate a third airflow 252, where the third airflow 252 and the third airflow 244 have the same direction, so as to improve the heat dissipating effect.

FIG. 5 is a top view of an electronic device according to still another embodiment of the invention. In the electronic device 300 of the present embodiment, configuration and operations of a first fan 340 and a second fan 350 are the same to that of the first fan 140 and the second fan 150 of FIG. 2, which are not repeated. A main difference between the electronic device 300 and the electronic device 100 is that the electronic device 300 further includes a third fan 350′ and a fourth fan 350″. The third fan 350′ and the fourth fan 350″ are disposed on a casing 310 and are respectively located at two sides of the first fan 340.

When the first fan 340 rotates reverse to generate a first airflow 342 to remove the dust on a heat dissipating element 330, the third fan 350′ also rotates reverse to generate a fourth airflow 354′, where the fourth airflow 354′ and the first airflow 342 have a same direction, so as to improve the dust removal effect. When the second fan 350 rotates reverse to generate a fourth airflow 354 to remove the dust in the casing 310, the fourth fan 350″ also rotates reverse to generate a fourth airflow 354″, where the fourth airflow 354″ and the fourth airflow 354 have a same direction, so as to improve the dust removal effect. When the first fan 340 rotates forward to generate a second airflow 344 to dissipate the heat of the heat dissipating element 330, the third fan 350′ also rotates forward to generate a third airflow 352′, where the third airflow 352′ and the second airflow 344 have a same direction, so as to improve the heat dissipating effect. When the second fan 350 rotates forward to generate a third airflow 352 to dissipate the heat in internal of the casing 310 or expel the dust in the casing 310, the fourth fan 350″ also rotates forward to generate a third airflow 352″, where the third airflow 352″ and the third airflow 352 have a same direction, so as to improve the heat dissipating effect or dust removal efficiency.

In summary, in the electronic device of the invention, the first fan disposed on the heat dissipating element is not only capable of rotating forward to dissipate the heat of the heat dissipating element, but is also capable of rotating reverse to remove the dust in the casing. In this way, dust removal of the heat dissipating device can be more convenient, so as to avoid accumulation of the dust in the casing to reduce heat dissipating efficiency. Moreover, the second fan disposed on the casing can rotate reverse to remove the dust in collaboration with the first fan, which improves the dust removal effect.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An electronic device, comprising:
a casing;
a heat generating element, disposed in the casing;
a heat dissipating element, disposed on the heat generating element; and
a first fan, disposed on the heat dissipating element, wherein when the electronic device is changed from a first state into a second state, the first fan rotates reverse to generate a first airflow, and after the first fan rotates reverse over a first time length, the first fan is changed to rotate forward to generate a second airflow.

2. The electronic device as claimed in claim 1, wherein the first state represents that the electronic device is in a turn-off state, and the second state represents that the electronic device is in a turn-on state.

3. The electronic device as claimed in claim 1, wherein the first airflow flows from the heat dissipating element to the first fan, and the second airflow flows from the first fan to the heat dissipating element.

4. The electronic device as claimed in claim 1, further comprising a second fan, wherein the second fan is disposed in the casing and is adapted to generate a third airflow flowing to an internal space of the casing.

5. The electronic device as claimed in claim 4, wherein when the electronic device is changed from the first state to the second state, the second fan generates a fourth airflow, and after the fourth airflow is maintained over a second time length, the second fan generates the third airflow, wherein the first time length is greater than the second time length.

6. The electronic device as claimed in claim 5, wherein the electronic device further comprises a motherboard disposed in the casing, the heat generating element is disposed on the motherboard, and the fourth airflow flows through the motherboard.

7. The electronic device as claimed in claim 4, further comprising:
a motherboard; and
a control module, disposed on the motherboard and configured to drive the first fan and the second fan,
wherein when a temperate in the casing is greater than a predetermined value, the control module controls the first fan and the second fan to rotate forward.

8. The electronic device as claimed in claim 7, wherein the control module further comprises a basic input output system, wherein the basic input output system is electrically connected to the first fan and the second fan, and is configured to set rotation speeds of the first fan and the second fan.

9. The electronic device as claimed in claim 8, wherein the control module comprises a control circuit, the control circuit is electrically connected to the first fan and the second fan, and is configured to set the first fan and the second fan to rotate forward or reverse and set operating time for the first fan and the second fan rotating forward or reverse.

10. The electronic device as claimed in claim 1, wherein the first state comprises a hibernation state of the electronic device.
